(19) United States
(12) Patent Application Publication
(10) Pub. No.: US 2006/0258056 A1
(43) Pub. Date: Nov. 16, 2006

(54) Method for producing a chip panel by means of a heating and pressing process using a thermoplastic material

(76) Inventor: Michael Bauer, Nittendorf (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 10/544,436

(22) PCT Filed: Feb. 3, 2004
(86) PCT No.: PCT/DE04/00164

§ 371 Date: May 8, 2006

(30) Foreign Application Priority Data
Feb. 5, 2003 (DE) 103 04 777.8

(51) Int. Cl. H01L 21/00

(52) U.S. Cl. 438/125

(57) ABSTRACT

The invention relates to a method for producing a chip panel or composite wafer by means of a heating and pressing process, and also to a device for carrying out the method. For carrying out the method, a chip carrier sheet and a transfer sheet are provided in the device. The method comprises loading the chip carrier sheet with semiconductor chips and heating the sheets. As this happens, one of the sheets remains dimensionally stable, while the semiconductor chips are pressed into the other, deformable sheet.

### BACKGROUND

A chip panel or composite wafer is a sheet of plastic connected to semiconductor chips, as known from the publication U.S. Pat. No. 6,072,234 by the term “neo-wafer”. The sheet of plastic comprises a dispensed or pressed plastic molding compound.

A chip panel often additionally has a redistribution routing substrate loaded with semiconductor chips. The upper side of the redistribution routing substrate, which carries the semiconductor chips, is covered by a plastic molding compound, embedding the semiconductor chips. The back side of the redistribution routing substrate has external contact areas, which can be loaded with external contacts. Such chip panels consequently have a number of electronic components and can be subsequently separated into individual electronic components. A disadvantage of these chip panels is their cost-intensive, complex construction, which can only be realized by means of cost-intensive method steps and complex devices.

### SUMMARY

The present invention provides a method and a device which lead to cost savings in the production of chip panels.

This invention is achieved by the subject matter of the independent claims. Advantageous developments of the invention emerge from the dependent claims.

In one embodiment, the invention provides a method for producing a chip panel which produces a chip panel in a simple way by means of a heating and pressing process using a thermoplastic material. For this purpose, firstly a chip carrier sheet is prepared. This chip carrier sheet is loaded on its upper side with semiconductor chips. These semiconductor chips are arranged on the chip carrier sheet in rows and columns, maintaining a spacing a between the columns and a spacing b between the rows. Furthermore, a transfer sheet is prepared.

One of the two sheets is deformably softened in a heating step, while the other remains dimensionally stable. Then, the transfer sheet and the chip carrier sheet are pressed together. As this happens, the semiconductor chips are pressed into the deformable transfer sheet or the deformable chip sheet until an upper side of the deformable transfer sheet or chip carrier sheet and the upper sides of the semiconductor chips form a common and substantially leveled upper side. After the pressing of the semiconductor chips into the deformable sheet, the dimensionally stable sheet is removed.

The method has the advantage that a panel on which the upper sides of the semiconductor chips are free of plastic and form a common upper side with the deformable plastic of the chip carrier sheet or the transfer sheet can be produced inexpensively by simple means. On this common, leveled upper side, redistribution routing patterns with external contact areas can then be applied with a precision and order of magnitude previously only possible on semiconductor wafers. This dispenses entirely with the production of redistribution routing substrates loaded with semiconductor chips, since the chip panel according to the invention with the embedded semiconductor chips and exposed upper sides of the semiconductor chips is available as a substrate for a redistribution routing pattern and for application of external contacts.

In the case of the method according to the invention, one of the two sheets which are used as the chip carrier sheet or the transfer sheet is heated above its glass transition temperature during the heating step, while the dimensionally stable sheet is kept at a temperature below the glass transition temperature. If the glass transition temperatures of the chip carrier sheet and the transfer sheet differ by approximately a power of ten, both can be produced from a thermoplastic material. Alternatively, the dimensionally stable sheet may be produced from a thermosetting material which is already cured and remains dimensionally stable up to its decomposition temperature, while the sheet into which the semiconductor chips are to be pressed during heating consists of a thermoplastic material with a relatively low glass transition temperature, which lies below the decomposition temperature of the thermosetting material.

A dimensionally stable transfer sheet may be a completely planar sheet, so that, when the transfer sheet and the chip carrier sheet are pressed together, a completely planar, common upper side is produced by the upper sides of the semiconductor chips and the upper side of the plastic of the chip carrier sheet. In this case, the upper sides of the semiconductor chips comprise integrated circuits with their freely accessible contact areas. Consequently, the method has the advantage that the contact areas no longer have to be exposed when a redistribution routing pattern is applied to the chip panel, since the upper side of the semiconductor chips remains free of the plastic molding compound of the chip carrier sheet and also no additional layer of plastic has to be applied to the upper sides of the semiconductor chips before redistribution routing. This dispenses with further, previously customary method steps, to be specific application of a common insulating layer and a method step for opening contact windows of the semiconductor chip in this common insulating layer before application of a redistribution routing pattern.

A device, in particular for carrying out the method according to the invention, has a transfer sheet of a material which is dimensionally stable during the heating step and is provided with stamping surfaces. In this case, the stamping surfaces are adapted in arrangement and size to the semiconductor chips on a deformable chip carrier sheet. Before the dimensionally stable transfer sheet and the chip carrier sheet loaded with semiconductor chips are pressed together, the stamping surfaces are aligned with the semiconductor chips, so that the stamping surfaces assist the penetration of the semiconductor chips into the deformable chip carrier sheet during the pressing together of the chip carrier sheet and the transfer sheet. Such a device has the advantage that the upper side of the transfer sheet does not touch the deformable material of the chip carrier sheet and adhesive bonding with it is avoided. In this case, the chip carrier sheet preferably comprises a thermoplastic material.

Alternatively, the device for carrying out the method according to the invention may have a transfer sheet of deformable material, such as a thermoplastic film, and the chip carrier sheet may comprise a dimensionally stable material. In this case, the semiconductor chips are arranged with their upper sides on the dimensionally stable chip carrier sheet. When the transfer sheet and the chip carrier sheet are heated and pressed together, the back sides and the edge sides of the semiconductor chips are pressed into the deformable transfer sheet. This produces on the upper side of the chip carrier sheet a plane which is formed by deformable material of the transfer sheet and the upper sides of the semiconductor chips. In the case of this alternative, the transfer sheet receives the semiconductor chips, while the dimensionally stable chip carrier sheet is subsequently removed, in order to ensure access to the contact areas on the upper side of the semiconductor chips and application of a redistribution routing pattern to the common plane comprising transfer sheet material and upper sides of the semiconductor chips.

For both variants, the device has a surface press. This surface press for its part has at least one heatable pressing surface, with which the transfer sheet and/or the chip carrier sheet can be heated above the lower of the two glass transition temperatures. The heated-up pressing surfaces with the transfer sheet or the chip carrier sheet are pressed precisely onto each other until there is leveling of the upper sides of the semiconductor chips and deformable material.

To sum up, it can be stated that the individual chips are applied with a defined spacing to a thermoplastic carrier to form a chip panel. The encapsulating and embedding of the individual chips takes place by heat and exposure to a defined force. This method and the device according to the invention are accompanied by the following advantages:
1) no chemical shrinkage,
2) the size of the panel is not limited by the material properties,
3) a positioning accuracy of the semiconductor chips is independent of the material of the panel,
4) a cost reduction during the step and repeat mounting,
5) no additional carrier materials or protective materials are required,
6) there is the possibility of using thermoplastics for the carrier sheet and the transfer sheet, which permits increased thermal and mechanical loading in downstream processes,
7) the possibility of using radiation-crosslinked thermoplastics, which after appropriate treatment, for example with beta rays, have thermosetting properties,
8) cost saving by the production of large panels,
9) use of low-cost materials,
10) cost reduction by testing the components in the panel.

On account of the properties of the thermoplastics and on account of the leveled common surface comprising surfaces of the semiconductor chips and surfaces of the plastic, thin-film techniques, such as sputtering, photolithography, galvanic reinforcement of metal layers and also dry and wet etching, can be used in an advantageous way for the further processing. Furthermore, with the aid of thick-film techniques, connecting lines that are wider by an order of magnitude can be produced. In addition, it is possible for the production of connecting lines to apply electrically conducting plastics to the common surface by means of dispensing.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic cross section of a device for carrying out the method according to the invention.

FIG. 2 illustrates a schematic cross section of an alternative device for carrying out the method according to the invention.

FIG. 3 illustrates a schematic cross section of a chip panel produced with the aid of one of the devices according to FIG. 1 or FIG. 2.

FIG. 4 illustrates a basic plan view of a chip panel according to FIG. 3.

### DETAILED DESCRIPTION

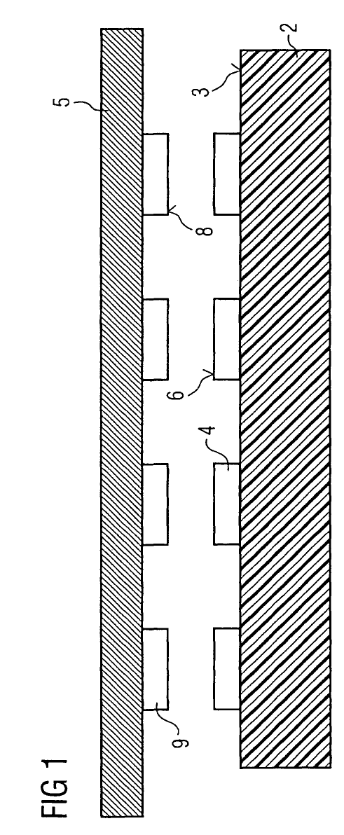

FIG. 1 illustrates a schematic cross section of a device for carrying out a method according to the invention. This device has a dimensionally stable transfer sheet 5, which is loaded with transfer stamps 9. Furthermore, the device has a deformable chip carrier sheet 2, which has semiconductor chips 4 arranged in rows and columns on its upper side 3. While the deformable chip carrier sheet 2 includes a thermoplastic material, the transfer sheet is dimensionally stable and produced from a thermosetting material. The glass transition temperature of the thermoplastic material of the chip carrier sheet 2 in this case lies below the decomposition temperature of the thermosetting material of the transfer sheet 5.

For forming the semiconductor chips into the thermoplastic material of the chip carrier sheet 2, the device can heat up the chip carrier sheet 2 and the transfer sheet 5 to a process temperature above the glass transition temperature of the chip carrier sheet 2 and below the decomposition temperature of the thermosetting material of the transfer sheet 5. Before moving the transfer sheet 5 and the chip carrier sheet 2 together, the sheets 2 and 5 are aligned with each other in such a way that the transfer stamps 9 are aligned with their stamping surfaces 8 congruent to the semiconductor chips 4 on the chip carrier sheet 2. In addition, the area size and arrangement of the stamping surfaces 8 are adapted to the upper sides 6 of the semiconductor chips 4.

After aligning the transfer sheet 5 and the chip carrier sheet 2 and heating the sheets 2 and 5, a device that is not shown, with pressing plates between which the chip carrier sheet 2 and the transfer sheet 5 are arranged, moves the two sheets 2 and 5 toward each other. As this happens, the transfer stamps 9 press the semiconductor chips 4 into the softened thermoplastic compound of the chip carrier sheet 2. The moving together of the transfer sheet 5 and the chip carrier sheet 2 is stopped when the upper sides 6 of the semiconductor chips 4 have been leveled with the upper side 3 of the deformable chip carrier sheet 2 and form a common upper side.

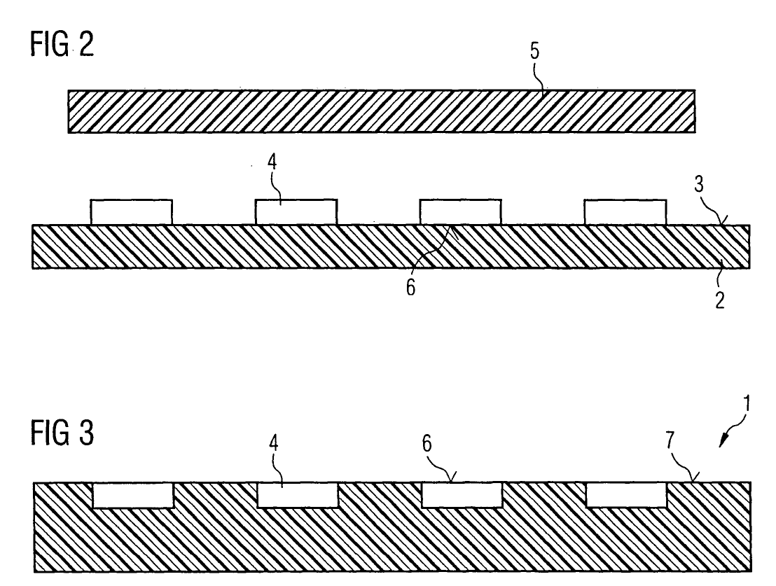

FIG. 2 illustrates a schematic cross section of an alternative device for carrying out a method according to the invention. In the case of the alternative device according to FIG. 2, the chip carrier sheet 2 comprises a plastic which is dimensionally stable at the process temperature. On the upper side 3 of the dimensionally stable chip carrier sheet 2, semiconductor chips 4 are arranged in rows and columns. In addition, the device has a transfer sheet 5, which consists of a thermoplastic material with a glass transition temperature which lies below the process temperature. When heatable pressing surfaces of a pressing device that is not shown are heated, the transfer sheet 5 softens. During the subsequent moving together of the pressing surfaces, the semiconductor chips 4 on the dimensionally stable chip carrier sheet 2 are pressed into the thermoplastic material of the transfer sheet 5.

The dimensionally stable chip carrier sheet 2 of glass, ceramic or a film of thermosetting material or a sheet of thermoplastic material with a higher glass transition temperature than the process temperature can be removed after the embedding of the semiconductor chips 4 in the deformable transfer sheet 5. Such removal is possible by blasting away, etching away, sputtering away or by pulling away for example a film of the cooled upper side of the transfer sheet 5 after embedding of the back sides and edge sides of the semiconductor chips 4 in the thermoplastic material of the transfer sheet 5.

The difference between the two devices lies on the one hand in the different materials of the chip carrier sheet 2 and the transfer sheet 5 and in the different arrangement of the semiconductor chips on the chip carrier sheet 2. In the method according to FIG. 1, the back sides of the semiconductor chips are arranged on the deformable chip carrier sheet 2. By contrast, in the method according to FIG. 2, the upper sides 6 of the semiconductor chips 4 are arranged on the upper side 3 of the dimensionally stable chip carrier sheet.

FIG. 3 illustrates a schematic cross section of a chip panel 1 produced with the aid of one of the devices according to FIG. 1 or FIG. 2. This chip panel 1 is distinguished by a common and leveled upper side 7 comprising upper sides 6 of the semiconductor chips 4 and upper sides either of a chip carrier sheet or a transfer sheet, as are shown in FIGS. 1 and 2. A redistribution routing pattern, which permits access to the exposed upper sides 6 of the semiconductor chips 4, and consequently to the integrated circuits of the semiconductor chips 4, can be applied to this common upper side 7 of the chip panel 1 without further intermediate steps. Furthermore, the redistribution routing pattern may be provided with external contact areas and these in turn may be provided with external contacts, so that such a chip panel can be produced with relatively few production steps and can be separated into individual electronic components.

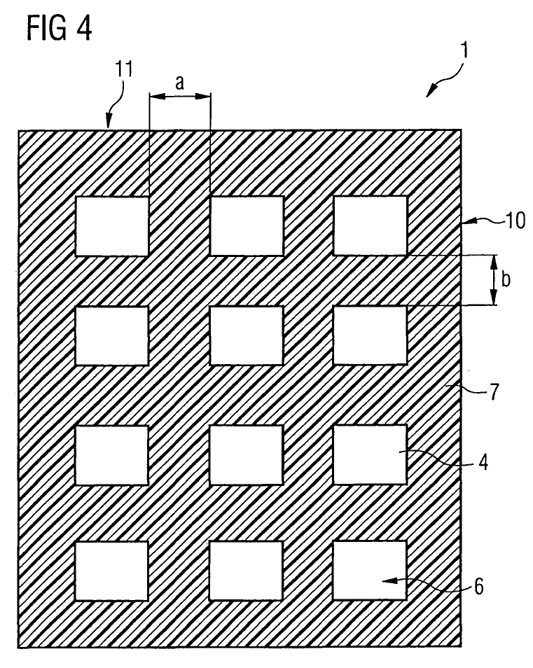

FIG. 4 illustrates a basic plan view of a chip panel according to FIG. 3. The upper sides 6 of the semiconductor chips 4 are in this case arranged in rows 10 and columns 11, the spacing a between columns 11 and the spacing b between rows 10 between the semiconductor chips 4 being filled with a thermoplastic molding compound. With the aid of such a chip panel 1, the available area for the arrangement of external contacts can be enlarged as much as desired with respect to the size purely of the chip surfaces, depending merely on the spacing a or the spacing b between the semiconductor chips.

1-5. (canceled)

6. A method for producing a chip panel comprising:
loading a deformable chip carrier sheet on an upper side with semiconductor chips
having an upper contact side;
providing a transfer sheet; and
pressing the deformable chip carrier sheet and the transfer sheet together, including pressing the semiconductor chips into the deformable chip carrier sheet until the upper side of the deformable chip carrier is substantially level with the upper contact side of the semiconductor chips.

7. The method of claim 6, comprising:
removing the transfer sheet.

8. The method of claim 6, comprising:
heating the deformable chip carrier sheet.

9. The method of claim 6, comprising:
defining the chip carrier sheet to include a thermoplastic material; and
defining the transfer sheet to be made of a dimensionally stable thermosetting material.

10. The method of claim 9, comprising:
defining a transition temperature of the thermoplastic material to be below a decomposition temperature of the thermosetting material.

11. The method of claim 6, comprising:
arranging the semiconductor chips on the deformable chip carrier sheet in rows and columns.

12. A method for producing a chip panel comprising:
loading a deformable chip carrier sheet on an upper side with semiconductor chips having an upper contact side;
loading a transfer sheet with transfer stamps having stamping surfaces;
pressing the deformable chip carrier sheet and the transfer sheet together, including pressing the semiconductor chips into the deformable chip carrier sheet until the upper side of the deformable chip carrier is substantially level with the upper contact side of the semiconductor chips.

13. The method of claim 11, comprising:
aligning the stamping surfaces congruent to the semiconductor chips on the deformable chip carrier sheet.

14. A method for producing a chip panel comprising:
loading a chip carrier sheet on an upper side with semiconductor chips having an upper contact side facing an upper side of the chip carrier sheet;
providing a deformable transfer sheet; and
pressing the chip carrier sheet and the deformable transfer sheet together, including pressing the semiconductor chips into the deformable transfer sheet until the upper contact side of the semiconductor chips is substantially level with a surface if the deformable transfer sheet; and
removing the chip carrier sheet.

15. The method of claim 14, comprising:
heating the deformable transfer sheet.

16. The method of claim 14, comprising:
defining the deformable transfer sheet to include a thermoplastic material; and
defining the chip carrier sheet to be made of a dimensionally stable thermosetting material.

17. The method of claim 16, comprising:
defining a transition temperature of the thermoplastic material to be below a decomposition temperature of the thermosetting material; and
heating the thermoplastic material to a temperature of the transition temperature.

18. The method of claim 14, comprising:
arranging the semiconductor chips on the deformable chip carrier sheet in rows and columns.

19. A method for producing a chip panel comprising:
loading a deformable chip carrier sheet on an upper side with semiconductor chips having an upper contact side;
providing a transfer sheet;
pressing the deformable chip carrier sheet and the transfer sheet together, including pressing the semiconductor chips into the deformable chip carrier sheet until the upper side of the deformable chip carrier is substantially level with the upper contact side of the semiconductor chips;
removing the transfer sheet; and
applying a redistribution routing pattern to the upper side of the chip carrier sheet.

20. The method of claim 19, comprising:
providing the redistribution routing pattern with external contact areas.

21. The method of claim 19, comprising:
defining the transfer sheet to be made of at least one of a group of materials consisting of a glass, a ceramic or a film.

22. The method of claim 19, comprising:
removing the transfer sheet using a etching process.

23. The method of claim 19, comprising:
removing the transfer sheet using a pulling process.

24. The method of claim 19, comprising:
removing the transfer sheet using a blasting process.

25. The method of claim 19, comprising:
removing the transfer sheet using a sputtering process.

26. A device suitable for performing the method of claim 6 comprising:
means for pressing the deformable chip carrier sheet and the transfer sheet together; and
means for heating the deformable chip carrier sheet.

27. The device of claim 26, comprising:
wherein the device has a surface press, between the heatable pressing surfaces of which the transfer sheet and the chip carrier sheet can be precisely pressed onto each other until there is leveling of the upper sides of the semiconductor chips and deformable material of the transfer sheet or the chip carrier sheet.

28. A semiconductor arrangement comprising:
a deformable chip carrier sheet loaded on an upper side with semiconductor chips having an upper contact side;
a transfer sheet loaded with transfer stamps having stamping surfaces; and
wherein the deformable chip carrier sheet and the transfer sheet are pressed together, including the semiconductor chips pressed into the deformable chip carrier sheet and the upper side of the deformable chip carrier is substantially level with the upper contact side of the semiconductor chips.
